(19) United States
(12) Patent Application Publication
(10) Pub. No.: US 2025/0316009 A1
(43) Pub. Date: Oct. 9, 2025

(54) SKETCH-TO-3D OBJECT CREATION

(71) Applicant: NVIDIA Corporation, Santa Clara, CA (US)

(72) Inventors: Chen Tessler, Zichron Yaakov (IL); Yoni Kasten, Modiin (IL); Gal Chechik, Ramat Hasharon (IL)

(21) Appl. No.: 18/629,775

(22) Filed: Apr. 8, 2024

(51) Int. Cl. G06T 11/80; G06T 5/70

(52) U.S. Cl. CPC G06T 11/80; G06T 5/70; G06T 2211/441

(57) ABSTRACT

Text-to-image generation generally refers to the process of generating an image from one or more text prompts input by a user and in some cases also a user provided sample image. Existing text-to-image generation processes are configured to only generate content from text and usually non-original sample images (e.g. obtained from the Internet). This limits the customization options available to the user. The present disclosure provides a sketch-to-3D content generation process which allows users to generate 3D content from a given 3D human generated, or free-form, sketch, which enables greater customization of computer generated 3D content.

### TECHNICAL FIELD

The present disclosure relates to processes for creating three-dimensional (3D) content from a given prompt.

### BACKGROUND

Recently there has been interest in computer processes that generate images from only a human provided natural language text prompt and, in some cases, also a human provided sample image. These processes are generally referred to text-to-image generation and they can be employed to ease the difficult task of traditional content creation processes which generally require a human content creator to have artistic training and, in the case of three-dimensional (3D) content, also require the human to have 3D modeling expertise.

However, as noted above, these text-to-image generation processes are configured to only generate content from text and usually non-original sample images (e.g. obtained from the Internet). This limits the customization options available to the human.

There is a need for addressing these issues and/or other issues associated with the prior art. For example, there is a need to be able to generate 3D content from a given 3D human generated, or free-form, sketch, to allow for greater customization of computer generated 3D content.

### SUMMARY

A method, computer readable medium, and system are disclosed for performing an optimization of a representation of a 3D object from a 3D free-form sketch of the 3D object. The representation of the 3D object is rendered from a defined camera position to generate a first two-dimensional (2D) image. Noise is added to the first 2D image to generate a noisy 2D image. The 3D free-form sketch of the 3D object is rendered from the defined camera position to generate a second 2D image. The noisy 2D image and the second 2D image are processed using a pretrained 2D sketch-to-2D image model to denoise the noisy 2D image and output a result as a denoised 2D image. The representation of the 3D object is updated based on a loss computed between the denoised 2D image and the first 2D image.

### BRIEF DESCRIPTION OF THE DRAWINGS

FIG. 1 illustrates a method for performing an optimization of a representation of a 3D object from a 3D free-form sketch of the 3D object, in accordance with an embodiment, in accordance with an embodiment.

FIG. 2 illustrates a system for performing an optimization of a representation of a 3D object from a 3D free-form sketch of the 3D object, in accordance with an embodiment.

FIG. 3 illustrates a schematic diagram of a process to optimize a 3D object representation using a free-form sketch, in accordance with an embodiment.

FIG. 4 illustrates a method for rendering a 2D image from a 3D object representation, in accordance with an embodiment.

FIG. 5 illustrates an example of a 3D free-form sketch and 2D images rendered from a 3D object representation optimized using the 3D free-from sketch, in accordance with an embodiment.

FIG. 6A illustrates inference and/or training logic, according to at least one embodiment;

FIG. 6B illustrates inference and/or training logic, according to at least one embodiment;

FIG. 7 illustrates training and deployment of a neural network, according to at least one embodiment;

FIG. 8 illustrates an example data center system, according to at least one embodiment.

### DETAILED DESCRIPTION

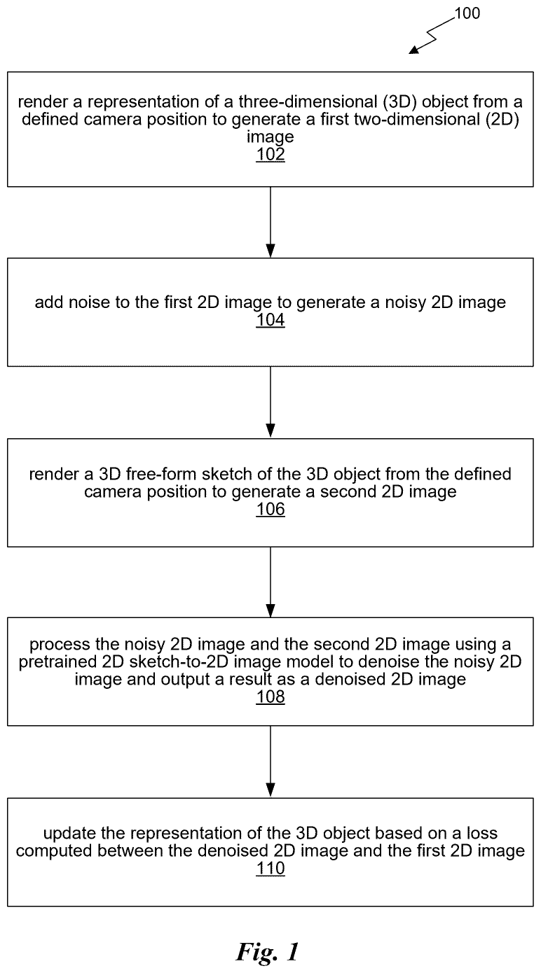

FIG. 1 illustrates a method 100 for performing an optimization of a representation of a 3D object from a 3D free-form sketch of the 3D object, in accordance with an embodiment. The method 100 may be performed by a device, which may be comprised of a processing unit, a program, custom circuitry, or a combination thereof, in an embodiment. In another embodiment a system comprised of a non-transitory memory storage comprising instructions, and one or more processors in communication with the memory, may execute the instructions to perform the method 100. In another embodiment, a non-transitory computer-readable media may store computer instructions which when executed by one or more processors of a device cause the device to perform the method 100.

In operation 102, representation of a 3D object is rendered from a defined camera position to generate a first 2D image. The 3D object refers to any physical object capable of being represented in three dimensions. In an embodiment, the object may exist in 3D in the real world.

Additionally, the representation of the 3D object (also referred to herein as a “3D object representation”) may be any type of representation from which a 2D image can be rendered (as described in more detail below). In an embodiment, the representation of the 3D object may be a neural radiance field (NeRF) model. In another embodiment, the representation of the 3D object may be a signed distance function. In another embodiment, the representation of the 3D object may be a mesh. In another embodiment, the representation of the 3D object may be a Gaussian Splatting representation.

In an embodiment, the representation of a 3D object may only partially depict the 3D object. For example, the representation of a 3D object may be missing areas of the 3D object and/or features of the 3D object. In an embodiment, the representation of the 3D object may be initialized randomly. In an embodiment, the representation of the 3D object may be may be initialized to a sphere (e.g. for surfaces [signed distance function (SDF) or mesh]).

As mentioned, the representation of the 3D object is rendered from a defined camera position to generate a first 2D image. The defined camera position refers to a position (e.g. viewing angle) of a camera with respect to the 3D object. In other words, the defined camera position may represent a particular viewpoint of the 3D object.

It should be noted that the defined camera position may be selected in any desired manner. In an embodiment, the defined camera position may be a randomly sampled camera position. In another embodiment, the defined camera position may be selected based on the 3D free-form sketch (described below). For example, the defined camera position may be selected as a camera position that captures a maximum amount of information from the 3D free-form sketch.

In an embodiment, the representation of the 3D object may be rendered from the defined camera position using a differentiable renderer. A differentiable renderer, in an embodiment, refers to hardware and/or software that operates on a 3D representation of an object, to get a 2D view of the 3D representation that is differentiable with respect to the 3D representation (i.e. it is possible to define how a change in the 3D representation affects each pixel in the rendered image). The differentiable renderer enables optimizing the 3D representation with the image based one or more loss functions, as described in more detail below. In any case, rendering the representation of the 3D object from the defined camera position results in generation of a first 2D image.

In operation 104, noise is added to the first 2D image to generate a noisy 2D image. In an embodiment, the noise may be Guassian noise. In an embodiment, the noise may be added to the first 2D image iteratively. In an embodiment, the 3D free-form sketch over a predefined number of iterations to progressively increase a level of noise in the first 2D image.

In operation 106, a 3D free-form sketch of the 3D object is rendered from the defined camera position to generate a second 2D image. The 3D free-form sketch refers to an at least partially free-handed sketch made by a user. Thus, the 3D free-form sketch of the 3D object may be manually generated by a user, at least in part without use of preconfigured shapes, textures, etc.

In an embodiment, the 3D free-form sketch may be given as an image of a physical (e.g. pen and paper) sketch made by the user. In another embodiment, the 3D free-form sketch may be given as a computer file generated by a computer application used by the user to make the 3D free-form sketch. The free-form sketch may be considered to be in 3D by including multiple sketches of different views of the 3D object or by being generated in 3D via the computer application.

The 3D free-form sketch is rendered from the same defined camera position as is used to render the representation of the 3D object. In an embodiment, the 3D free-form sketch may also be rendered using a differentiable renderer. Regardless, rendering the 3D free-form sketch of the 3D object from the defined camera position results in generation of a second 2D image.

In operation 108, the noisy 2D image and the second 2D image are processed using a pretrained 2D sketch-to-2D image model to denoise the noisy 2D image and output a result as a denoised 2D image. The pretrained 2D sketch-to-2D image model refers to a machine learning model that has already been trained to generate a 2D image from an input 2D sketch. In an embodiment, the pretrained 2D sketch-to-2D image model may be pretrained on pairs of 2D sketches and 2D images. In an embodiment, the pretrained 2D sketch-to-2D image model may also allow text input along with the sketch to generate a 2D image. In an embodiment, the pretrained 2D sketch-to-2D image model may be a diffusion model. In an embodiment, the pretrained 2D sketch-to-2D image model may be a multi-layer perceptron (MLP).

As mentioned, the pretrained 2D sketch-to-2D image model denoises the noisy 2D image and outputs a denoised 2D image as a result. In an embodiment, the second 2D image may be input to the pretrained 2D sketch-to-2D image model as a control signal that constrains the pretrained 2D sketch-to-2D image model during the denoising of the noisy 2D image. In an embodiment, a user-provided (e.g. natural language) text may also be input to the pretrained 2D sketch-to-2D image model as another control signal that constrains the pretrained 2D sketch-to-2D image model during the denoising of the noisy 2D image. In an embodiment, the 2D sketch-to-2D image model may operate to iteratively denoise the noisy 2D image.

In operation 110, the representation of the 3D object is updated based on a loss computed between the denoised 2D image and the first 2D image. The loss refers to a computed difference between the denoised 2D image generated by the 2D sketch-to-2D image model and the first 2D image rendered from the given representation of the 3D object. In an embodiment, the loss may be a Score Distillation Sampling (SDS) loss.

The representation of the 3D object may be updated in any manner that is based on the loss and that operates to improve (e.g. optimize) the representation of the 3D object. In an embodiment, updating the representation of the 3D object may include adjusting weights and/or other parameters of the representation of the 3D object.

In an embodiment, the method 100 to optimize the representation of the 3D object from the 3D free-form sketch of the 3D object may be repeated over one or more additional iterations, with each iteration being for a different defined camera position. In this way, the representation of the 3D object may be incrementally updated (e.g. until a threshold level of optimization is achieved). In an embodiment, the optimization is repeated until a stopping criteria is met. For example, the stopping criteria may be the 2D sketch-to-2D image model achieving less than a threshold level of loss).

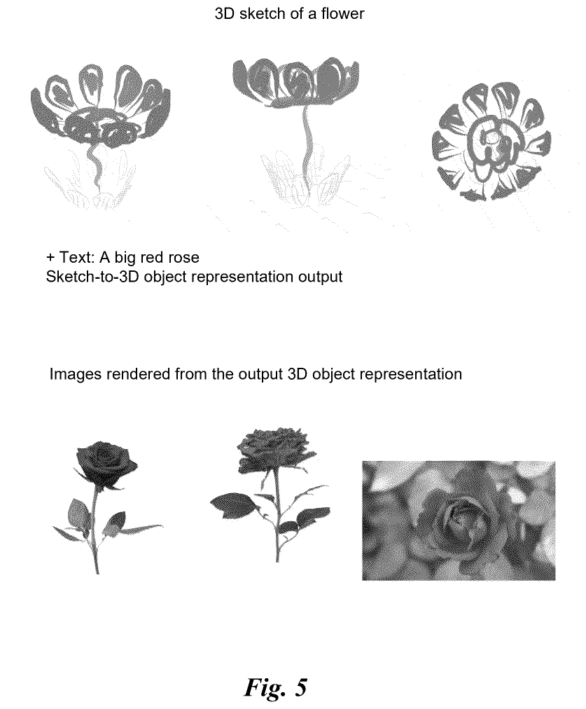

It should be noted that the method 100 may include performing the optimization of the 3D object representation at test time (as opposed to training time). In an embodiment, a result of the optimization may be an optimized representation of the 3D object. In an embodiment, the optimized representation of the 3D object may be renderable from a user-selected viewpoint for presentation to the user, for example as described with respect to FIG. 5 below.

In one exemplary implementation of the method 100, a representation of a 3D object is optimized from a 3D free-form sketch of the 3D object by: rendering a first 2D image from a specified viewpoint of the representation of the 3D object; adding noise to the first 2D image to generate a noisy 2D image; rendering a second 2D image from the specified viewpoint of the 3D free-form sketch of the 3D object; using a pretrained 2D sketch-to-2D image model to denoise the noisy 2D image with the second 2D image as a control signal, wherein an output of the pretrained 2D sketch-to-2D image model is a denoised 2D image; and updating the representation of the 3D object based on a loss computed between the denoised 2D image and the first 2D image.

Further embodiments will now be provided in the description of the subsequent figures. It should be noted that the embodiments disclosed herein with reference to the method 100 of FIG. 1 may apply to and/or be used in combination with any of the embodiments of the remaining figures below.

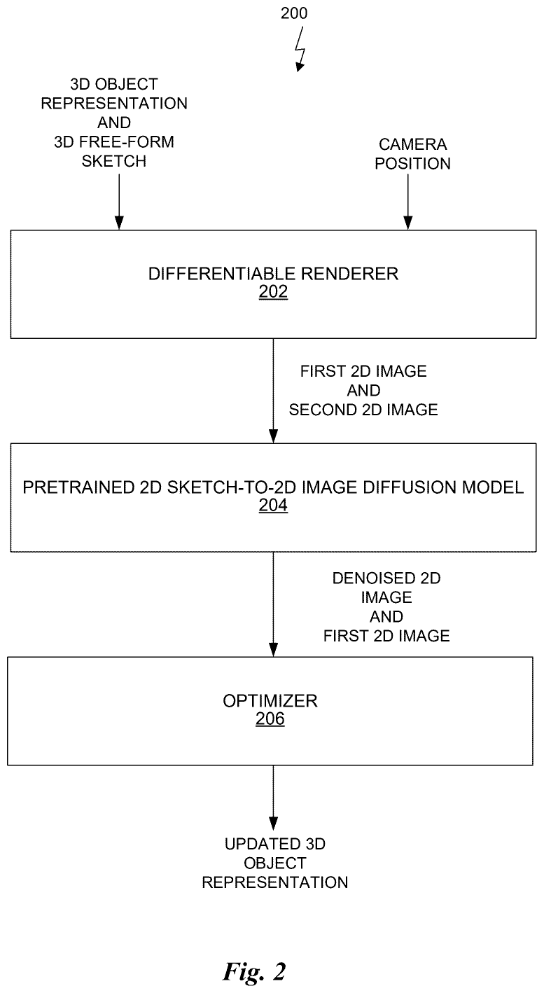

FIG. 2 illustrates a system 200 for performing an optimization of a representation of a 3D object from a 3D free-form sketch of the 3D object, in accordance with an embodiment. The system 200 may be implemented to carry out the method 100 of FIG. 1, for example. Of course, however, the system 200 may be implemented in any desired context. It should be noted that the descriptions and definitions provided above may equally apply to the present description.

The system 200 includes a differentiable renderer 202, a pretrained 2D sketch-to-2D image diffusion model 204, and an optimizer 206. These system components 202-206 may be implemented in computer hardware, software, or a combination thereof.

A 3D object representation and a 3D free-form sketch are input to a differentiable renderer 202, both of which correspond to a same 3D object. A defined camera position is also input to the differentiable renderer 202. The 3D object representation may be provided by a user or an application. The 3D free-form sketch may be provided by the user. The camera position may be provided by the application.

The differentiable renderer 202 renders a first 2D image of the 3D object representation from the camera position. The differentiable renderer 202 also renders a second 2D image of the 3D free-form sketch from the camera position. The differentiable renderer 202 outputs both the first 2D image and the second 2D image to the pretrained 2D sketch-to-2D image diffusion model 204.

The pretrained 2D sketch-to-2D image diffusion model 204 processes the first 2D image and the second 2D image to generate a third 2D image. In particular, the pretrained 2D sketch-to-2D image diffusion model 204 may add noise to the first 2D image in a forward diffusion process. The pretrained 2D sketch-to-2D image diffusion model 204 then may remove the added noise in a reverse diffusion process with using the second 2D image as a constraint during the denoising process. The output of the pretrained 2D sketch-to-2D image diffusion model 204 is a denoised 2D image.

The denoised 2D image output by the pretrained 2D sketch-to-2D image diffusion model 204 is input to the optimizer 206 along with the first 2D image generated by the differentiable renderer 202. The optimizer 206 processes the denoised 2D image to update, or optimize, the 3D object representation. In particular, the optimizer 206 computes a loss between the denoised 2D image and the first 2D image, and then updates the 3D object representation based on the loss. For example, the model 204 predicts the noise (“noise_prediction”), which is already known because it was added to the clean image (“gt_noise”). The optimizer 206 can accordingly compute the loss as: loss=norm (“gt_noise”−“noise_prediction”). This may also be considered as loss=norm (“denoised_image”−“original_image”) because “denoised_image”=“original_image”+“gt_noise”−“noise_prediction”. Therefore norm (“denoised_image”−“original_image”)=norm (“original_image”+“at_noise”-“noise_prediction”-original_image”)=norm (“gt_noise”-“noise_prediction”).

This system 200 process may then repeat using the updated 3D object representation and a newly defined camera position. In an embodiment, the system 200 process may repeat a defined number of times for specified different camera positions. In another embodiment, the system 200 process may repeat until a stopping criteria has been met, such as the loss computed by the optimizer 206 being below a defined threshold.

Output of the system 200 is an updated, or optimized, 3D object representation which has been learned using the 3D free-form sketch. The updated 3D object representation may then be used to render 2D images of the 3D object from any given viewpoint.

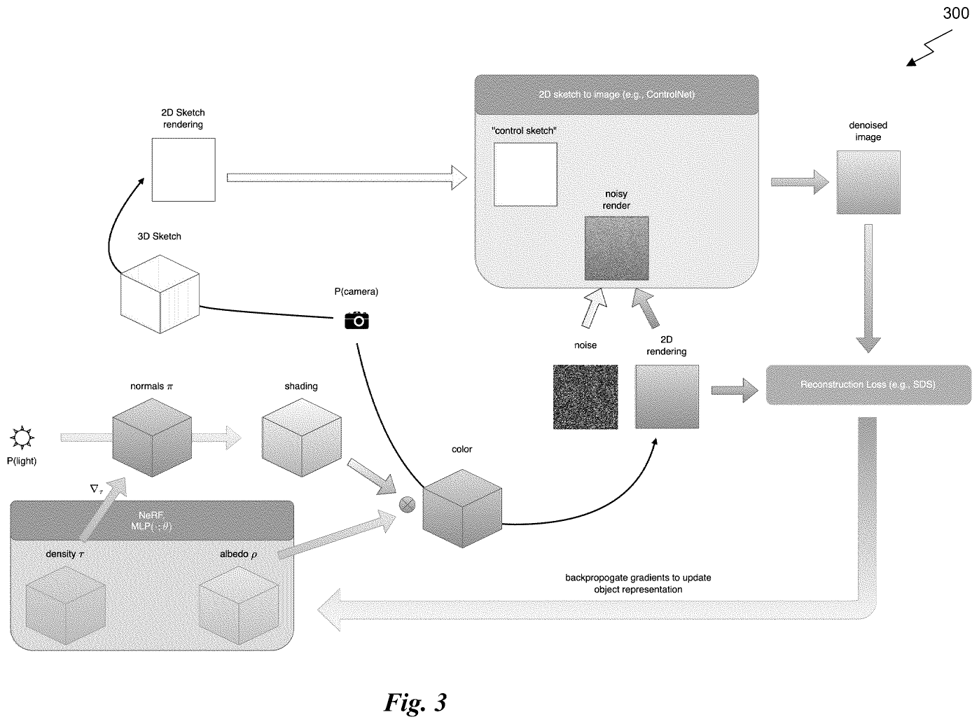

FIG. 3 illustrates a schematic diagram of a process 300 to optimize a 3D object representation using a free-form sketch, in accordance with an embodiment. The process 300 may be carried out using the system 200 of FIG. 2, in an embodiment. Again, it should be noted that the descriptions and definitions provided above may equally apply to the present description.

The process 300 takes a 3D free-form sketch and an “in-training” 3D object representation, and uses differentiable rendering to render 2D images of both the 3D free-form sketch and the “in-training” 3D object representation from the same camera position and angle. This produces two 2D images that represent the same 3D object from the same perspective.

The two 2D images are provided to a pretrained 2D sketch-to-image model which returns a 2D image. An example is ControlNet where the 2D sketch is the “control signal” constraining what the model should do. Some noise is applied to the 2D image of the “in training” object. This noisy image is provided to the pretrained 2D sketch-to-image model to denoise, or in other words to predict the added noise. Text can also be provided as further guidance to the pretrained 2D sketch-to-image model.

The resulting image from the pretrained 2D sketch-to-image model is compared with the 2D image previously rendered from the “in-training” 3D object representation. The loss is then used as a basis for updating, or optimizing, the “in-training” 3D object representation. Since the 2D image renderings mentioned above are generated using differentiable rendering, this objective can be used to obtain gradients for learning the 3D object representation. For example, the loss may be an SDS loss which encourages the predicted noise to be as close as possible to the added (known) noise.

When the pretrained 2D sketch-to-image model predicts the noise successfully (e.g. as indicated by the loss being lower than a defined threshold), then it can be assumed that the 2D image previously rendered from the “in training” 3D object representation is consistent with the distribution of the pretrained 2D sketch-to-image model (so it looks like a natural image), and it ca also be assume that the 2D image previously rendered from the “in training” 3D object representation is consistent with the 2D image rendered from the 3D free-form sketch.

In an embodiment, this process 300 may take random views of the same “in training” 3D representation and the same 3D sketch, such that by the end of this process 300 the 3D object representation looks natural, and consistent with the 3D free-form sketch.

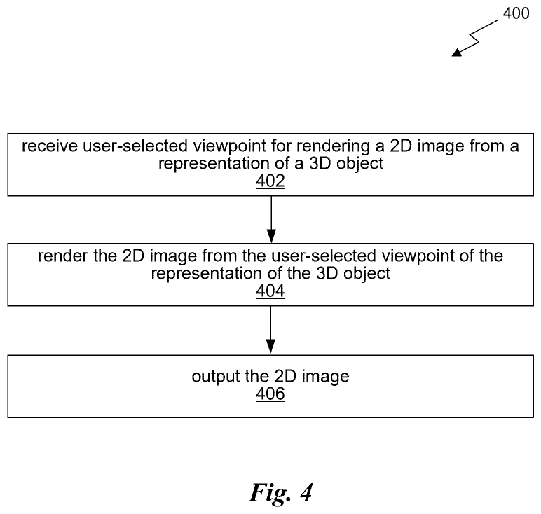

FIG. 4 illustrates a method 400 for rendering a 2D image from a 3D object representation, in accordance with an embodiment. The method 400 may be performed in the context of any of FIGS. 1-3. In particular, the method 400 may be performed using the optimized 3D object representation generated in accordance with any of the embodiments disclosed herein.

In operation 402, a user-selected viewpoint is received for rendering a 2D image from a 3D object representation. In operation 404, the 2D image is rendered from the user-selected viewpoint of the 3D object representation. In operation 406, the 2D image is output (e.g. to a display).

Of course, it should be noted that while the viewpoint is disclosed to be “user-selected,” other embodiments are contemplated in which the viewpoint is selected by a computer application or as part of any computer process functioning to cause the 2D image to be rendered. For example, as some examples of a practical use of the 3D object representation, the 3D object representation may be used to show the object (e.g. in 3D) in video games, to present the object (e.g. in 3D) in a simulation environment, to print the object in 3D by a 3D printer, etc.

FIG. 5 illustrates an example of a 3D free-form sketch and 2D images rendered from a 3D object representation optimized using the 3D free-from sketch, in accordance with an embodiment. As shown, the 3D free-form sketch includes multiple perspectives of a flower. The 3D free-form sketch, along with the input text “A big red rose” is used by a pretrained 2D sketch-to-2D image model to generate a 3D representation of the flower, per the embodiments of any of FIGS. 1-3. 2D images of the 3D representation of the flower can then be generated, as illustrated.

### Machine Learning

Deep neural networks (DNNs), including deep learning models, developed on processors have been used for diverse use cases, from self-driving cars to faster drug development, from automatic image captioning in online image databases to smart real-time language translation in video chat applications. Deep learning is a technique that models the neural learning process of the human brain, continually learning, continually getting smarter, and delivering more accurate results more quickly over time. A child is initially taught by an adult to correctly identify and classify various shapes, eventually being able to identify shapes without any coaching. Similarly, a deep learning or neural learning system needs to be trained in object recognition and classification for it get smarter and more efficient at identifying basic objects, occluded objects, etc., while also assigning context to objects.

At the simplest level, neurons in the human brain look at various inputs that are received, importance levels are assigned to each of these inputs, and output is passed on to other neurons to act upon. An artificial neuron or perceptron is the most basic model of a neural network. In one example, a perceptron may receive one or more inputs that represent various features of an object that the perceptron is being trained to recognize and classify, and each of these features is assigned a certain weight based on the importance of that feature in defining the shape of an object.

A deep neural network (DNN) model includes multiple layers of many connected nodes (e.g., perceptrons, Boltzmann machines, radial basis functions, convolutional layers, etc.) that can be trained with enormous amounts of input data to quickly solve complex problems with high accuracy. In one example, a first layer of the DNN model breaks down an input image of an automobile into various sections and looks for basic patterns such as lines and angles. The second layer assembles the lines to look for higher level patterns such as wheels, windshields, and mirrors. The next layer identifies the type of vehicle, and the final few layers generate a label for the input image, identifying the model of a specific automobile brand.

Once the DNN is trained, the DNN can be deployed and used to identify and classify objects or patterns in a process known as inference. Examples of inference (the process through which a DNN extracts useful information from a given input) include identifying handwritten numbers on checks deposited into ATM machines, identifying images of friends in photos, delivering movie recommendations to over fifty million users, identifying and classifying different types of automobiles, pedestrians, and road hazards in driverless cars, or translating human speech in real-time.

During training, data flows through the DNN in a forward propagation phase until a prediction is produced that indicates a label corresponding to the input. If the neural network does not correctly label the input, then errors between the correct label and the predicted label are analyzed, and the weights are adjusted for each feature during a backward propagation phase until the DNN correctly labels the input and other inputs in a training dataset. Training complex neural networks requires massive amounts of parallel computing performance, including floating-point multiplications and additions. Inferencing is less compute-intensive than training, being a latency-sensitive process where a trained neural network is applied to new inputs it has not seen before to classify images, translate speech, and generally infer new information.

### Inference and Training Logic

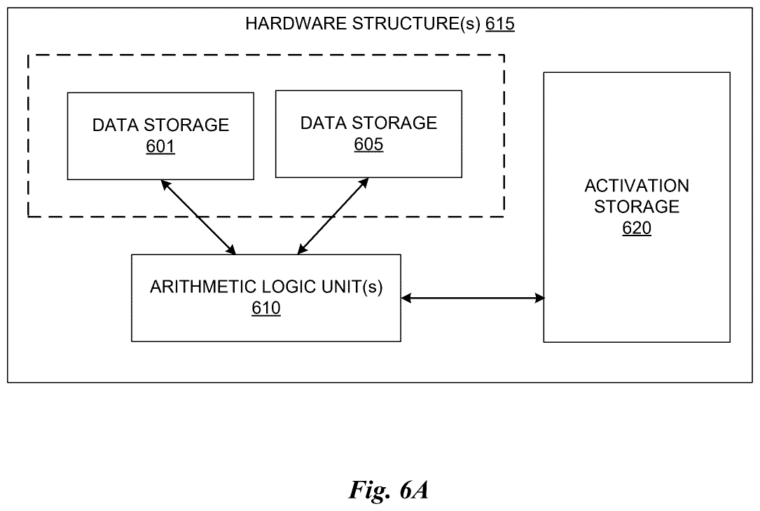

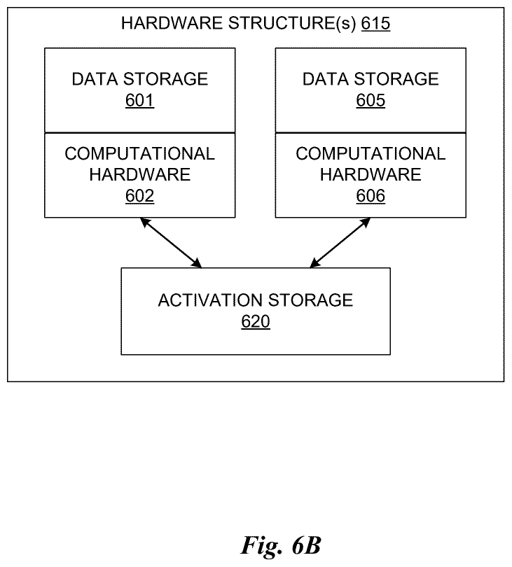

As noted above, a deep learning or neural learning system needs to be trained to generate inferences from input data. Details regarding inference and/or training logic 615 for a deep learning or neural learning system are provided below in conjunction with FIGS. 6A and/or 6B.

In at least one embodiment, inference and/or training logic 615 may include, without limitation, a data storage 601 to store forward and/or output weight and/or input/output data corresponding to neurons or layers of a neural network trained and/or used for inferencing in aspects of one or more embodiments. In at least one embodiment data storage 601 stores weight parameters and/or input/output data of each layer of a neural network trained or used in conjunction with one or more embodiments during forward propagation of input/output data and/or weight parameters during training and/or inferencing using aspects of one or more embodiments. In at least one embodiment, any portion of data storage 601 may be included with other on-chip or off-chip data storage, including a processor's L1, L2, or L3 cache or system memory.

In at least one embodiment, any portion of data storage 601 may be internal or external to one or more processors or other hardware logic devices or circuits. In at least one embodiment, data storage 601 may be cache memory, dynamic randomly addressable memory (“DRAM”), static randomly addressable memory (“SRAM”), non-volatile memory (e.g., Flash memory), or other storage. In at least one embodiment, choice of whether data storage 601 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, inference and/or training logic 615 may include, without limitation, a data storage 605 to store backward and/or output weight and/or input/output data corresponding to neurons or layers of a neural network trained and/or used for inferencing in aspects of one or more embodiments. In at least one embodiment, data storage 605 stores weight parameters and/or input/output data of each layer of a neural network trained or used in conjunction with one or more embodiments during backward propagation of input/output data and/or weight parameters during training and/or inferencing using aspects of one or more embodiments. In at least one embodiment, any portion of data storage 605 may be included with other on-chip or off-chip data storage, including a processor's L1, L2, or L3 cache or system memory. In at least one embodiment, any portion of data storage 605 may be internal or external to on one or more processors or other hardware logic devices or circuits. In at least one embodiment, data storage 605 may be cache memory, DRAM, SRAM, non-volatile memory (e.g., Flash memory), or other storage. In at least one embodiment, choice of whether data storage 605 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, data storage 601 and data storage 605 may be separate storage structures. In at least one embodiment, data storage 601 and data storage 605 may be same storage structure. In at least one embodiment, data storage 601 and data storage 605 may be partially same storage structure and partially separate storage structures. In at least one embodiment, any portion of data storage 601 and data storage 605 may be included with other on-chip or off-chip data storage, including a processor's L1, L2, or L3 cache or system memory.

In at least one embodiment, inference and/or training logic 615 may include, without limitation, one or more arithmetic logic unit(s) (“ALU(s)”) 610 to perform logical and/or mathematical operations based, at least in part on, or indicated by, training and/or inference code, result of which may result in activations (e.g., output values from layers or neurons within a neural network) stored in an activation storage 620 that are functions of input/output and/or weight parameter data stored in data storage 601 and/or data storage 605. In at least one embodiment, activations stored in activation storage 620 are generated according to linear algebraic and or matrix-based mathematics performed by ALU(s) 610 in response to performing instructions or other code, wherein weight values stored in data storage 605 and/or data 601 are used as operands along with other values, such as bias values, gradient information, momentum values, or other parameters or hyperparameters, any or all of which may be stored in data storage 605 or data storage 601 or another storage on or off-chip. In at least one embodiment, ALU(s) 610 are included within one or more processors or other hardware logic devices or circuits, whereas in another embodiment, ALU(s) 610 may be external to a processor or other hardware logic device or circuit that uses them (e.g., a co-processor). In at least one embodiment, ALUs 610 may be included within a processor's execution units or otherwise within a bank of ALUs accessible by a processor's execution units either within same processor or distributed between different processors of different types (e.g., central processing units, graphics processing units, fixed function units, etc.). In at least one embodiment, data storage 601, data storage 605, and activation storage 620 may be on same processor or other hardware logic device or circuit, whereas in another embodiment, they may be in different processors or other hardware logic devices or circuits, or some combination of same and different processors or other hardware logic devices or circuits. In at least one embodiment, any portion of activation storage 620 may be included with other on-chip or off-chip data storage, including a processor's L1, L2, or L3 cache or system memory. Furthermore, inferencing and/or training code may be stored with other code accessible to a processor or other hardware logic or circuit and fetched and/or processed using a processor's fetch, decode, scheduling, execution, retirement and/or other logical circuits.

In at least one embodiment, activation storage 620 may be cache memory, DRAM, SRAM, non-volatile memory (e.g., Flash memory), or other storage. In at least one embodiment, activation storage 620 may be completely or partially within or external to one or more processors or other logical circuits. In at least one embodiment, choice of whether activation storage 620 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors. In at least one embodiment, inference and/or training logic 615 illustrated in FIG. 6A may be used in conjunction with an application-specific integrated circuit (“ASIC”), such as Tensorflow® Processing Unit from Google, an inference processing unit (IPU) from Graphcore™, or a Nervana® (e.g., “Lake Crest”) processor from Intel Corp. In at least one embodiment, inference and/or training logic 615 illustrated in FIG. 6A may be used in conjunction with central processing unit (“CPU”) hardware, graphics processing unit (“GPU”) hardware or other hardware, such as field programmable gate arrays (“FPGAs”).

FIG. 6B illustrates inference and/or training logic 615, according to at least one embodiment. In at least one embodiment, inference and/or training logic 615 may include, without limitation, hardware logic in which computational resources are dedicated or otherwise exclusively used in conjunction with weight values or other information corresponding to one or more layers of neurons within a neural network. In at least one embodiment, inference and/or training logic 615 illustrated in FIG. 6B may be used in conjunction with an application-specific integrated circuit (ASIC), such as Tensorflow® Processing Unit from Google, an inference processing unit (IPU) from Graphcore™, or a Nervana® (e.g., “Lake Crest”) processor from Intel Corp. In at least one embodiment, inference and/or training logic 615 illustrated in FIG. 6B may be used in conjunction with central processing unit (CPU) hardware, graphics processing unit (GPU) hardware or other hardware, such as field programmable gate arrays (FPGAs). In at least one embodiment, inference and/or training logic 615 includes, without limitation, data storage 601 and data storage 605, which may be used to store weight values and/or other information, including bias values, gradient information, momentum values, and/or other parameter or hyperparameter information. In at least one embodiment illustrated in FIG. 6B, each of data storage 601 and data storage 605 is associated with a dedicated computational resource, such as computational hardware 602 and computational hardware 606, respectively. In at least one embodiment, each of computational hardware 606 comprises one or more ALUs that perform mathematical functions, such as linear algebraic functions, only on information stored in data storage 601 and data storage 605, respectively, result of which is stored in activation storage 620.

In at least one embodiment, each of data storage 601 and 605 and corresponding computational hardware 602 and 606, respectively, correspond to different layers of a neural network, such that resulting activation from one “storage/computational pair 601/602” of data storage 601 and computational hardware 602 is provided as an input to next “storage/computational pair 605/606” of data storage 605 and computational hardware 606, in order to mirror conceptual organization of a neural network. In at least one embodiment, each of storage/computational pairs 601/602 and 605/606 may correspond to more than one neural network layer. In at least one embodiment, additional storage/computation pairs (not shown) subsequent to or in parallel with storage computation pairs 601/602 and 605/606 may be included in inference and/or training logic 615.

### Neural Network Training and Deployment

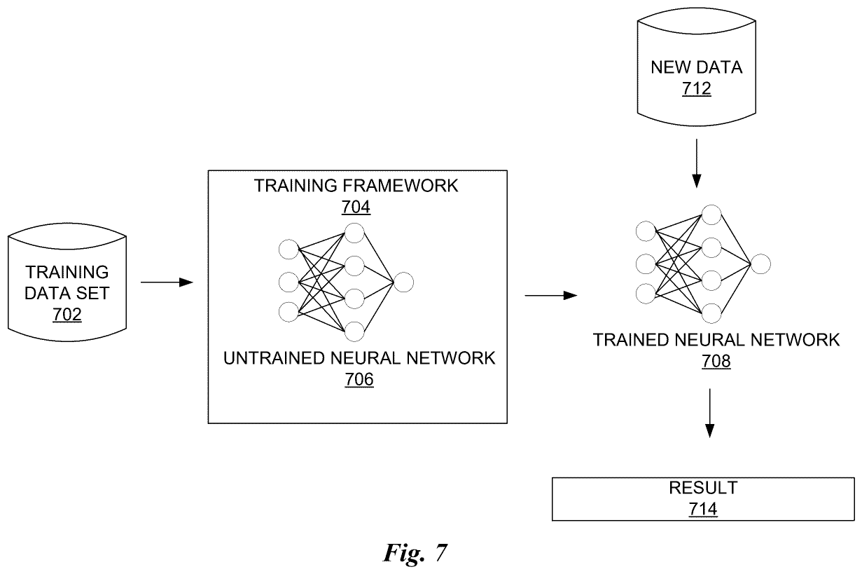

FIG. 7 illustrates another embodiment for training and deployment of a deep neural network. In at least one embodiment, untrained neural network 706 is trained using a training dataset 702. In at least one embodiment, training framework 704 is a PyTorch framework, whereas in other embodiments, training framework 704 is a Tensorflow, Boost, Caffe, Microsoft Cognitive Toolkit/CNTK, MXNet, Chainer, Keras, Deeplearning4j, or other training framework. In at least one embodiment training framework 704 trains an untrained neural network 706 and enables it to be trained using processing resources described herein to generate a trained neural network 708. In at least one embodiment, weights may be chosen randomly or by pre-training using a deep belief network. In at least one embodiment, training may be performed in either a supervised, partially supervised, or unsupervised manner.

In at least one embodiment, untrained neural network 706 is trained using supervised learning, wherein training dataset 702 includes an input paired with a desired output for an input, or where training dataset 702 includes input having known output and the output of the neural network is manually graded. In at least one embodiment, untrained neural network 706 is trained in a supervised manner processes inputs from training dataset 702 and compares resulting outputs against a set of expected or desired outputs. In at least one embodiment, errors are then propagated back through untrained neural network 706. In at least one embodiment, training framework 704 adjusts weights that control untrained neural network 706. In at least one embodiment, training framework 704 includes tools to monitor how well untrained neural network 706 is converging towards a model, such as trained neural network 708, suitable to generating correct answers, such as in result 714, based on known input data, such as new data 712. In at least one embodiment, training framework 704 trains untrained neural network 706 repeatedly while adjust weights to refine an output of untrained neural network 706 using a loss function and adjustment algorithm, such as stochastic gradient descent. In at least one embodiment, training framework 704 trains untrained neural network 706 until untrained neural network 706 achieves a desired accuracy. In at least one embodiment, trained neural network 708 can then be deployed to implement any number of machine learning operations.

In at least one embodiment, untrained neural network 706 is trained using unsupervised learning, wherein untrained neural network 706 attempts to train itself using unlabeled data. In at least one embodiment, unsupervised learning training dataset 702 will include input data without any associated output data or “ground truth” data. In at least one embodiment, untrained neural network 706 can learn groupings within training dataset 702 and can determine how individual inputs are related to untrained dataset 702. In at least one embodiment, unsupervised training can be used to generate a self-organizing map, which is a type of trained neural network 708 capable of performing operations useful in reducing dimensionality of new data 712. In at least one embodiment, unsupervised training can also be used to perform anomaly detection, which allows identification of data points in a new dataset 712 that deviate from normal patterns of new dataset 712.

In at least one embodiment, semi-supervised learning may be used, which is a technique in which in training dataset 702 includes a mix of labeled and unlabeled data. In at least one embodiment, training framework 704 may be used to perform incremental learning, such as through transferred learning techniques. In at least one embodiment, incremental learning enables trained neural network 708 to adapt to new data 712 without forgetting knowledge instilled within network during initial training.

### Data Center

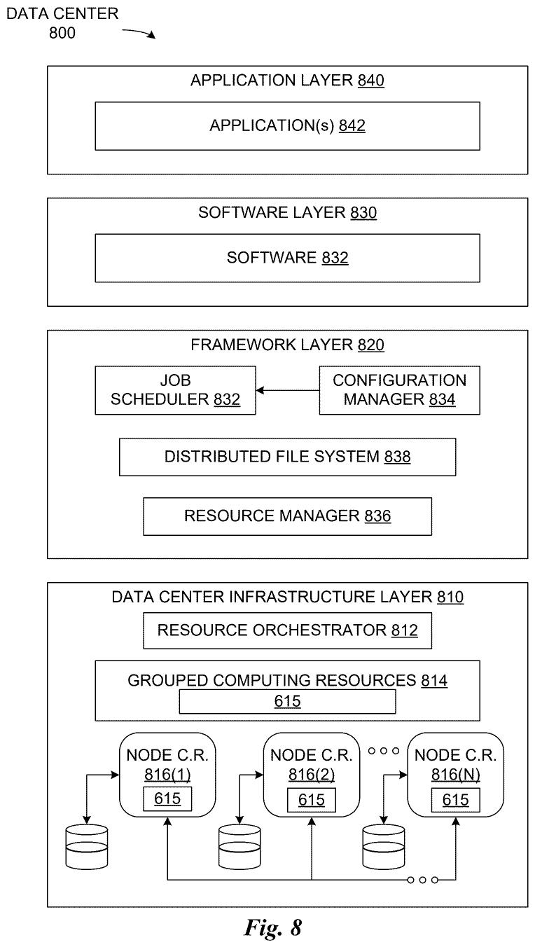

FIG. 8 illustrates an example data center 800, in which at least one embodiment may be used. In at least one embodiment, data center 800 includes a data center infrastructure layer 810, a framework layer 820, a software layer 830 and an application layer 840.

In at least one embodiment, as shown in FIG. 8, data center infrastructure layer 810 may include a resource orchestrator 812, grouped computing resources 814, and node computing resources (“node C.R.s”) 816(1)-816(N), where “N” represents any whole, positive integer. In at least one embodiment, node C.R.s 816(1)-816(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 816(1)-816(N) may be a server having one or more of above-mentioned computing resources.

In at least one embodiment, grouped computing resources 814 may include separate groupings of node C.R.s housed within one or more racks (not shown), or many racks housed in data centers at various geographical locations (also not shown). Separate groupings of node C.R.s within grouped computing resources 814 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 822 may configure or otherwise control one or more node C.R.s 816(1)-816(N) and/or grouped computing resources 814. In at least one embodiment, resource orchestrator 822 may include a software design infrastructure (“SDI”) management entity for data center 800. In at least one embodiment, resource orchestrator may include hardware, software or some combination thereof.

In at least one embodiment, as shown in FIG. 8, framework layer 820 includes a job scheduler 832, a configuration manager 834, a resource manager 836 and a distributed file system 838. In at least one embodiment, framework layer 820 may include a framework to support software 832 of software layer 830 and/or one or more application(s) 842 of application layer 840. In at least one embodiment, software 832 or application(s) 842 may respectively include web-based service software or applications, such as those provided by Amazon Web Services, Google Cloud and Microsoft Azure. In at least one embodiment, framework layer 820 may be, but is not limited to, a type of free and open-source software web application framework such as Apache Spark™ (hereinafter “Spark”) that may utilize distributed file system 838 for large-scale data processing (e.g., “big data”). In at least one embodiment, job scheduler 832 may include a Spark driver to facilitate scheduling of workloads supported by various layers of data center 800. In at least one embodiment, configuration manager 834 may be capable of configuring different layers such as software layer 830 and framework layer 820 including Spark and distributed file system 838 for supporting large-scale data processing. In at least one embodiment, resource manager 836 may be capable of managing clustered or grouped computing resources mapped to or allocated for support of distributed file system 838 and job scheduler 832. In at least one embodiment, clustered or grouped computing resources may include grouped computing resource 814 at data center infrastructure layer 810. In at least one embodiment, resource manager 836 may coordinate with resource orchestrator 812 to manage these mapped or allocated computing resources.

In at least one embodiment, software 832 included in software layer 830 may include software used by at least portions of node C.R.s 816(1)-816(N), grouped computing resources 814, and/or distributed file system 838 of framework layer 820. one or more types of software may include, but are not limited to, Internet web page search software, e-mail virus scan software, database software, and streaming video content software.

In at least one embodiment, application(s) 842 included in application layer 840 may include one or more types of applications used by at least portions of node C.R.s 816(1)-816(N), grouped computing resources 814, and/or distributed file system 838 of framework layer 820. one or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 834, resource manager 836, and resource orchestrator 812 may implement any number and type of self-modifying actions based on any amount and type of data acquired in any technically feasible fashion. In at least one embodiment, self-modifying actions may relieve a data center operator of data center 800 from making possibly bad configuration decisions and possibly avoiding underutilized and/or poor performing portions of a data center.

In at least one embodiment, data center 800 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 800. In at least one embodiment, trained machine learning models corresponding to one or more neural networks may be used to infer or predict information using resources described above with respect to data center 800 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 615 are used to perform inferencing and/or training operations associated with one or more embodiments. In at least one embodiment, inference and/or training logic 615 may be used in system FIG. 8 for inferencing or predicting operations based, at least in part, on weight parameters calculated using neural network training operations, neural network functions and/or architectures, or neural network use cases described herein.

As described herein with reference to FIGS. 1-5, a method, computer readable medium, and system are disclosed for 3D sketch-to-3D object content creation, which relies on a pretrained 2D sketch-to-2D image model. The model may be stored (partially or wholly) in one or both of data storage 601 and 605 in inference and/or training logic 615 as depicted in FIGS. 6A and 6B. Training and deployment of the model may be performed as depicted in FIG. 7 and described herein. Distribution of the model may be performed using one or more servers in a data center 800 as depicted in FIG. 8 and described herein.

What is claimed is:

1. A method, comprising:
at a device, optimizing a representation of a three-dimensional (3D) object from a 3D free-form sketch of the 3D object by:
rendering a first two-dimensional (2D) image from a specified viewpoint of the representation of the 3D object;
adding noise to the first 2D image to generate a noisy 2D image;
rendering a second 2D image from the specified viewpoint of the 3D free-form sketch of the 3D object;
using a pretrained 2D sketch-to-2D image model to denoise the noisy 2D image with the second 2D image as a control signal, wherein an output of the pretrained 2D sketch-to-2D image model is a denoised 2D image; and
updating the representation of the 3D object based on a loss computed between the denoised 2D image and the first 2D image.

2. The method of claim 1, wherein the representation of the 3D object is one of:
a neural radiance field (NeRF) model,
a signed distance function
a mesh, or
a Gaussian Splatting representation.

3. The method of claim 1, wherein the 3D free-form sketch of the 3D object is manually generated by a user.

4. The method of claim 1, wherein the pretrained 2D sketch-to-2D image model is a machine learning model pretrained on pairs of 2D sketches and 2D images.

5. The method of claim 1, wherein the pretrained 2D sketch-to-2D image model is a diffusion model.

6. The method of claim 1, wherein the second 2D image constrains the pretrained 2D sketch-to-2D image model during the denoising of the noisy 2D image.

7. The method of claim 6, wherein a user provided text is further used as another control signal that constrains the pretrained 2D sketch-to-2D image model during the denoising of the noisy 2D image.

8. The method of claim 1, wherein updating the representation of the 3D object includes:
adjusting weights of the representation of the 3D object.

9. The method of claim 1, wherein the method further comprises, at the device:
repeating the optimizing of the updated representation of the 3D object using a different viewpoint.

10. The method of claim 9, wherein the optimizing is repeated over one or more iterations until a stopping criteria is met.

11. The method of claim 1, wherein a result of the optimizing is an optimized representation of the 3D object.

12. The method of claim 11, wherein the optimized representation of the 3D object is renderable from a user-selected viewpoint for presentation to the user.

13. A method, comprising:
at a device, performing an optimization of a representation of a three-dimensional (3D) object from a 3D free-form sketch of the 3D object by:
rendering the representation of the 3D object from a defined camera position to generate a first two-dimensional (2D) image;
adding noise to the first 2D image to generate a noisy 2D image;
rendering the 3D free-form sketch of the 3D object from the defined camera position to generate a second 2D image;
processing the noisy 2D image and the second 2D image using a pretrained 2D sketch-to-2D image model to denoise the noisy 2D image and output a result as a denoised 2D image; and
updating the representation of the 3D object based on a loss computed between the denoised 2D image and the first 2D image.

14. The method of claim 13, wherein the representation of the 3D object is a neural radiance field (NeRF) model.

15. The method of claim 13, wherein the representation of the 3D object is a signed distance function.

16. The method of claim 13, wherein the representation of the 3D object is a mesh.

17. The method of claim 13, wherein the representation of the 3D object is a Gaussian Splatting representation.

18. The method of claim 13, wherein the 3D free-form sketch of the 3D object is manually generated by a user.

19. The method of claim 13, wherein the defined camera position is a randomly sampled camera position.

20. The method of claim 13, wherein the defined camera position is selected based on the 3D free-form sketch.

21. The method of claim 13, wherein the defined camera position is selected as a camera position that captures a maximum amount of information from the 3D free-form sketch.

22. The method of claim 13, wherein the representation of the 3D object is rendered from the defined camera position using a differentiable renderer.

23. The method of claim 13, wherein the pretrained 2D sketch-to-2D image model is a machine learning model pretrained on pairs of 2D sketches and 2D images.

24. The method of claim 13, wherein the pretrained 2D sketch-to-2D image model is a diffusion model.

25. The method of claim 13, wherein the pretrained 2D sketch-to-2D image model is a multi-layer perceptron (MLP).

26. The method of claim 13, wherein the second 2D image is input to the pretrained 2D sketch-to-2D image model as a control signal that constrains the pretrained 2D sketch-to-2D image model during the denoising of the noisy 2D image.

27. The method of claim 26, wherein a user-provided text is further input to the pretrained 2D sketch-to-2D image model as another control signal that constrains the pretrained 2D sketch-to-2D image model during the denoising of the noisy 2D image.

28. The method of claim 13, wherein the loss is a Score Distillation Sampling (SDS) loss.

29. The method of claim 13, wherein updating the representation of the 3D object includes:
adjusting weights of the representation of the 3D object.

30. The method of claim 13, further comprising, at the device:
repeating the optimization over one or more additional iterations each for a different defined camera position.

31. The method of claim 30, wherein the optimization is repeated until a stopping criteria is met.

32. The method of claim 13, wherein the optimization is performed at test time.

33. The method of claim 13, wherein a result of the optimization is an optimized representation of the 3D object.

34. The method of claim 33, wherein the optimized representation of the 3D object is renderable from a user-selected viewpoint for presentation to the user.

35. A system, comprising:
a non-transitory memory storage comprising instructions; and
one or more processors in communication with the memory, wherein the one or more processors execute the instructions to perform an optimization of a representation of a three-dimensional (3D) object from a 3D free-form sketch of the 3D object by:
rendering the representation of the 3D object from a defined camera position to generate a first two-dimensional (2D) image;
adding noise to the first 2D image to generate a noisy 2D image;
rendering the 3D free-form sketch of the 3D object from the defined camera position to generate a second 2D image;
processing the noisy 2D image and the second 2D image using a pretrained 2D sketch-to-2D image model to denoise the noisy 2D image and output a result as a denoised 2D image; and
updating the representation of the 3D object based on a loss computed between the denoised 2D image and the first 2D image.

36. The system of claim 35, wherein the representation of the 3D object is one of:
a neural radiance field (NeRF) model,
a signed distance function,
a mesh, or
a Gaussian Splatting representation.

37. The system of claim 35, wherein the 3D free-form sketch of the 3D object is manually generated by a user.

38. The system of claim 35, wherein the defined camera position is one of:
a randomly sampled camera position,
selected based on the 3D free-form sketch, or
selected as a camera position that captures a maximum amount of information from the 3D free-form sketch.

39. The system of claim 35, wherein the representation of the 3D object is rendered from the defined camera position using a differentiable renderer.

40. The system of claim 35, wherein the pretrained 2D sketch-to-2D image model is a machine learning model pretrained on pairs of 2D sketches and 2D images.

41. The system of claim 35, wherein the second 2D image is input to the pretrained 2D sketch-to-2D image model as a control signal that constrains the pretrained 2D sketch-to-2D image model during the denoising of the noisy 2D image.

42. The system of claim 41, wherein a user-provided text is further input to the pretrained 2D sketch-to-2D image model as another control signal that constrains the pretrained 2D sketch-to-2D image model during the denoising of the noisy 2D image.

43. The system of claim 35, wherein the loss is a Score Distillation Sampling (SDS) loss.

44. The system of claim 35, wherein updating the representation of the 3D object includes:
adjusting weights of the representation of the 3D object.

45. The system of claim 35, further comprising, at the device:
repeating the optimization over one or more additional iterations each for a different defined camera position,
wherein the optimization is repeated until a stopping criteria is met.

46. The system of claim 35, wherein a result of the optimization is an optimized representation of the 3D object, and wherein the optimized representation of the 3D object is renderable from a user-selected viewpoint for presentation to the user.

47. A non-transitory computer-readable media storing computer instructions which when executed by one or more processors of a device cause the device to perform an optimization of a representation of a three-dimensional (3D) object from a 3D free-form sketch of the 3D object by:
rendering the representation of the 3D object from a defined camera position to generate a first two-dimensional (2D) image;
adding noise to the first 2D image to generate a noisy 2D image;
rendering the 3D free-form sketch of the 3D object from the defined camera position to generate a second 2D image;
processing the noisy 2D image and the second 2D image using a pretrained 2D sketch-to-2D image model to denoise the noisy 2D image and output a result as a denoised 2D image; and
updating the representation of the 3D object based on a loss computed between the denoised 2D image and the first 2D image.

48. The non-transitory computer-readable media of claim 47, wherein the representation of the 3D object is one of:
a neural radiance field (NeRF) model,
a signed distance function,
a mesh, or
a Gaussian Splatting representation.

49. The non-transitory computer-readable media of claim 47, wherein the 3D free-form sketch of the 3D object is manually generated by a user.

50. The non-transitory computer-readable media of claim 47, wherein the pretrained 2D sketch-to-2D image model is a machine learning model pretrained on pairs of 2D sketches and 2D images.

51. The non-transitory computer-readable media of claim 47, wherein the second 2D image is input to the pretrained 2D sketch-to-2D image model as a control signal that constrains the pretrained 2D sketch-to-2D image model during the denoising of the noisy 2D image.

52. The non-transitory computer-readable media of claim 51, wherein a user-provided text is further input to the pretrained 2D sketch-to-2D image model as another control signal that constrains the pretrained 2D sketch-to-2D image model during the denoising of the noisy 2D image.

53. The non-transitory computer-readable media of claim 47, wherein the loss is a Score Distillation Sampling (SDS) loss.

54. The non-transitory computer-readable media of claim 47, wherein updating the representation of the 3D object includes:
adjusting weights of the representation of the 3D object.

55. The non-transitory computer-readable media of claim 47, further comprising, at the device:
repeating the optimization over one or more additional iterations each for a different defined camera position,
wherein the optimization is repeated until a stopping criteria is met.

56. The non-transitory computer-readable media of claim 47, wherein a result of the optimization is an optimized representation of the 3D object, and wherein the optimized representation of the 3D object is renderable from a user-selected viewpoint for presentation to the user.
